(19) United States
(12) Patent Application Publication
(10) Pub. No.: US 2025/0309153 A1
(43) Pub. Date: Oct. 2, 2025

(54) Apparatus and Method for Mitigating Crosstalk in an Advanced Package

(71) Applicant: Chipletz, Inc, Spicewood, TX (US)

(72) Inventors: Ching-Ping Wong, Cupertino, CA (US); Lawrence Ross, Tuscon, AZ (US); Victor Kronberg, Austin, TX (US)

(73) Assignee: Chipletz, Inc., Spicewood, TX (US)

(21) Appl. No.: 18/754,504

(22) Filed: Jun. 26, 2024

Related U.S. Application Data
(60) Provisional application No. 63/570,299, filed on Mar. 27, 2024.

(51) Int. Cl. H01L 23/66; H01L 21/48; H01L 23/498

(52) U.S. Cl. CPC H01L 23/66; H01L 21/4846; H01L 23/49838; H01L 2223/6616

(57) ABSTRACT

An advanced semiconductor package substrate with crosstalk mitigation structures and methods of developing the same are provided. More particularly, methods and apparatus in an integrated circuit to mitigate crosstalk between signal traces disposed in a common layout plane of an advanced package are provided. Mitigation structures may be formed by providing at least one reference trace which substantially conforms to the path of that signal trace, essentially following the path of least impedance of the high frequency signal excitation.

### CROSS-REFERENCE TO RELATED APPLICATIONS

This application:
1. claims the benefit of, Provisional Application Ser. No. 63/570,299, filed 27 Mar. 2024 (“Parent Provisional”).

This application is related to:
1. U.S. application Ser. No. 17/692,587, filed 22 Mar. 2022 (“First Related Application”);
2. U.S. application Ser. No. 18/138,050, filed 22 Apr. 2023 (“Second Related Application”); which in turn is related to Provisional Application Ser. No. 63/334,449, filed 25 Apr. 2022 (“First Related Provisional”);
3. U.S. application Ser. No. 18/206,933, filed 7 Jun. 2023 (“Third Related Application”); which in turn is related to Provisional Application Ser. No. 63/349,920, filed 7 Jun. 2022 (“Second Related Provisional”);
4. U.S. application Ser. No. 18/378,235, filed 10 Oct. 2023 (“Fourth Related Application”); which in turn is related to Provisional Application Ser. No. 63/414,778, filed 10 Oct. 2022 (“Third Related Provisional”); and
5. U.S. application Ser. No. 18/429,374, filed 31 Jan. 2024 (“Fifth Related Application”); which in turn is related to Provisional Application Ser. No. 63/442,438, filed 31 Jan. 2023 (“Fourth Related Provisional”);
   collectively referred to hereinafter as the “Related Applications”.

This application claims priority to:
1. the Parent Provisional;
   collectively, “Priority References”, and hereby claims benefit of the filing dates thereof pursuant to 37 C.F.R. § 1.78 (a).

The subject matter of the Priority References and the Related Applications, each in its entirety, are expressly incorporated herein by reference.

### FIELD OF INVENTION

The present invention relates to the field of integrated circuits. More particularly, it relates to methods and apparatus in an integrated circuit to mitigate crosstalk between signal traces disposed in a common layout plane of an advanced package.

### BACKGROUND

In general, in the descriptions that follow, the first occurrence of each special term of art that should be familiar to those skilled in the art of integrated circuits (“ICs”) and systems will be italicized. In addition, when a term that may be new or that may be used in a context that may be new, that term will be set forth in bold and at least one appropriate definition for that term will be provided.

Hereinafter, reference to a facility shall mean a circuit or an associated set of circuits adapted to perform a particular function regardless of the physical layout of an embodiment thereof. Thus, the electronic elements comprising a given facility may be instantiated in the form of a hard macro adapted to be placed as a physically contiguous module, or in the form of a soft macro the elements of which may be distributed in any appropriate way that meets speed path requirements. In general, electronic systems comprise many different types of facilities, each adapted to perform specific functions in accordance with the intended capabilities of each system. Depending on the intended system application, the several facilities comprising the hardware platform may be integrated onto a single IC, or distributed across multiple ICs. Depending on cost and other known considerations, the electronic components, including the facility-instantiating IC(s), may be embodied in one or more single- or multi-chip packages. However, unless expressly stated to the contrary, the form of instantiation of any facility shall be considered as being purely a matter of design choice.

In the field of electronics, crosstalk is any phenomenon by which a signal transmitted on one circuit of a transmission system creates an undesired effect in another circuit or channel. Crosstalk is usually caused by undesired capacitive, inductive, or conductive coupling from one circuit or channel to another. In integrated circuit design, crosstalk normally refers to a signal conducted along one signal trace affecting a signal conducted along another, nearby signal trace. Usually, the coupling is capacitive, and to the nearest neighbor, but other forms of coupling and effects on signal further away are sometimes important, especially in analog designs.

Shown in FIG. 1A is one prior art solution, known as “stripline”, for mitigating crosstalk between adjacent signal traces, invented by Robert M. Barrett of the Air Force Cambridge Research Center in the 1950s. In this approach, a flat strip of metal, i.e., the signal trace, embedded in a dielectric medium is then sandwiched between two parallel ground planes.

Shown in FIG. 1B is another prior art solution, known as “microstrip”, for mitigating crosstalk between adjacent signal traces, developed by ITT laboratories as a competitor to stripline (Grieg, D. D.; Engelmann, H. F. (December 1952). “Microstrip-A New Transmission Technique for the Klilomegacycle Range”. Proceedings of the IRE. 40 (12): 1644-1650.) In this approach, the signal trace is separated from a ground plane by a dielectric layer generally referred to as a substrate.

In both the stripline and the microstrip technologies, one or more ground planes are required. In modern integrated circuit designs, it is not unusual to implement more than one voltage domains, each of which may have a reference plane that is independent not just of the primary ground/reference plane of the main power source but also independent of one or more of the other reference planes. In some designs, one or more chiplets are combined using interposers into a single advanced package. In prior art packaging known to me, the crosstalk-mitigating ground planes add additional manufacturing steps, cost and complexity to the final package.

As is known, at low frequencies, the signal return path follows the least resistance on the reference plane, e.g., in FIG. 2A, from point E directly to point P, where point A is the excitation origin. At high frequencies, the signal return path follows the least impedance on the reference plane, e.g., in FIG. 2B, from point E to point D, then to point C, then to point B and then to point A, again where point A is the excitation origin. Most transmission line problems are high frequency, in Giga Hertz.

What is needed, I submit, is a crosstalk-mitigating process that will tend to reduce the number of reference planes in an advanced package. In accordance with my invention, instead of utilizing a solid reference plane, as in the prior art known to me, for each signal trace I provide at least one reference trace which substantially conforms to the path of that signal trace, essentially following the path of least impedance of the high frequency signal excitation.

### BRIEF SUMMARY OF THE INVENTION

According to one embodiment, a method is described for manufacturing a substantially planar layer, the method comprising the steps of: forming an electrically-conductive signal trace having a first width W1 and a height T; forming an electrically-conductive reference trace laterally adjacent to the signal trace, the reference trace having a second width W2, a height substantially equal to T, and spaced from the signal trace by a third width S1, wherein S1 is less than T; and forming the layer by embedding the signal trace and the reference trace in a dielectric medium.

According to a second embodiment, a method is described comprising the steps of: forming an electrically-conductive signal trace having: a first side; a second side opposite said first side; a top side; a bottom side opposite said first side; a first width, W1, between said first side and said second side; and a height, T, between said top side and said bottom side; forming a first electrically-conductive reference trace laterally adjacent to a selected first side of the signal trace, the first reference trace having a second width W2, a height substantially equal to T, and spaced from the first side of the signal trace by a third width S1, wherein S1 is less than T; forming a second electrically-conductive reference trace laterally adjacent to a selected second side of the signal trace, the second reference trace having said second width W2, a height substantially equal to T, and spaced from the second side of the signal trace by said third width S1; and forming a substantially planar layer by embedding the signal trace and the reference traces in a dielectric medium.

According to a third embodiment, an electrically-conductive layer is disclosed comprising: an electrically-conductive signal trace having: a first side; a second side opposite said first side; a top side; a bottom side opposite said first side; a first width, W1, between said first side and said second side; and a height, T, between said top side and said bottom side; a first electrically-conductive reference trace laterally adjacent to a selected first side of the signal trace, the first reference trace having a second width W2, a height substantially equal to T, and spaced from the first side of the signal trace by a third width S1, wherein S1 is less than T; a second electrically-conductive reference trace laterally adjacent to a selected second side of the signal trace, the second reference trace having said second width W2, a height substantially equal to T, and spaced from the second side of the signal trace by said third width S1; and a substantially planar layer of dielectric medium embedding the signal trace and the reference traces.

In other embodiments, the electrically-conductive layers as disclosed herein comprise one or more layers of an advanced package.

### BRIEF DESCRIPTION OF THE SEVERAL VIEWS OF THE DRAWINGS

FIG. 1A illustrates one prior art solution, known as “stripline”;

FIG. 1B illustrates another prior art solution, known as “microstrip”;

FIG. 2, comprising FIG. 2A and FIG. 2B, illustrates typical signal return paths of low and high frequency signals, respectively;

FIG. 3, comprising FIGS. 3A, 3B, 3C and 3D, illustrates several possible embodiments of my invention;

FIG. 4, comprising FIGS. 4A and 4B, illustrates additional embodiments of my invention.

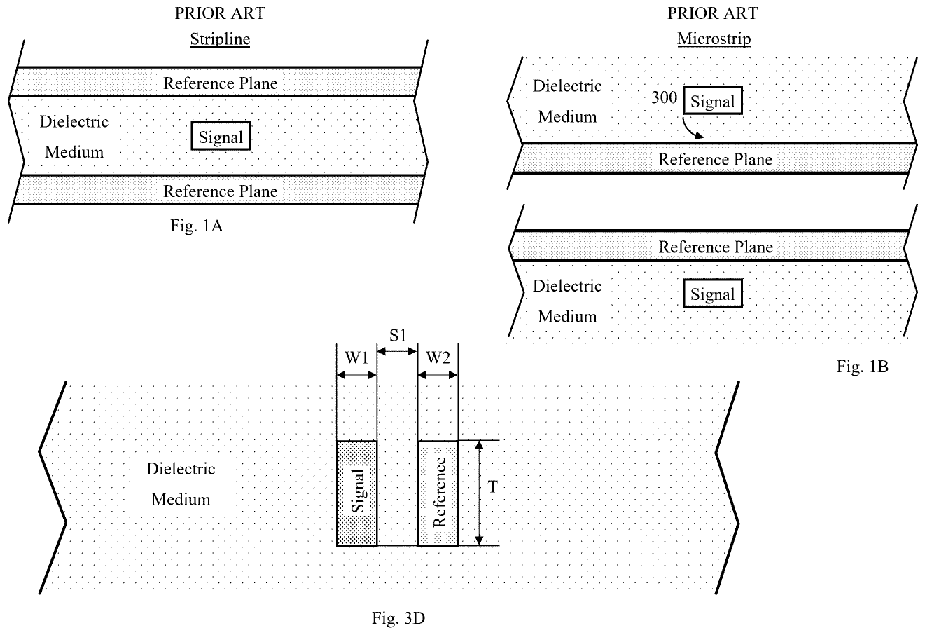

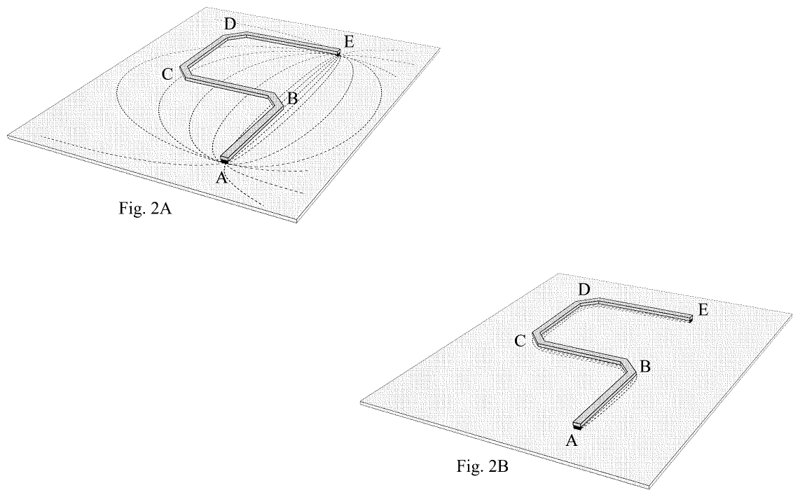

### DETAILED DESCRIPTION

The following description provides different embodiments for implementing aspects of the present invention. Specific examples of components and arrangements are described below to simplify the explanation. These are merely examples and are not intended to be limiting. For example, the description of a first component coupled to a second component includes embodiments in which the two components are directly connected, as well as embodiments in which an additional component is disposed between the first and second components. In addition, the present disclosure repeats reference numerals in various examples. This repetition is for the purpose of clarity and does not in itself require an identical relationship between the embodiments.

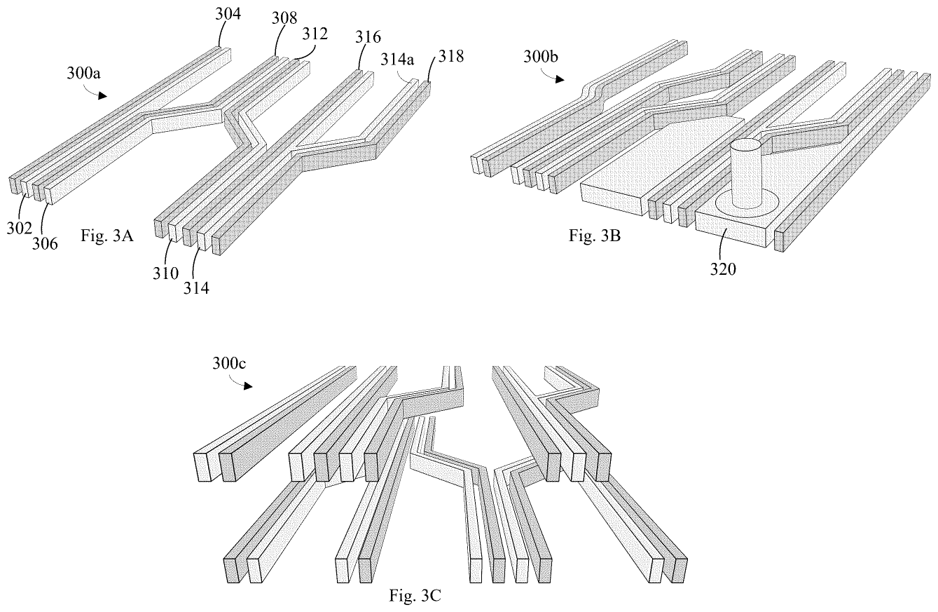

FIG. 3A illustrates, in perspective form, one exemplary embodiment of my invention. In this single-layer embodiment 300a, I have depicted in light gray four (4) separate and distinct signal traces, 302, 306, 310 and 314, each having a width of W1 and height of T (see, FIG. 3D). In addition, in accordance with my invention, I have depicted in medium gray four (4) separate and distinct reference traces, 304, 308, 312 and 316, each having a width of W2 and a height substantially equal to T (again, see, FIG. 3D). (Note 1: by “substantially equal” I mean that, due to planarization process variabilities, the final heights of the signal and reference traces may not be precisely equal, but still within specifications.). Further, also in accordance with my invention, each the reference trace is disposed laterally adjacent to a respective one of the signal traces. (Note 2: by “laterally adjacent” is mean that the signal traces and the reference traces are substantially coplanar, with each reference trace being disposed adjacent to a respective one of the signal traces.) Please note that my signal trace 314 has a “fork” 314a off to the right (in the perspective of this illustration) that is not shielded by the reference trace 316. To protect this fork 314a, I have added an additional reference trace 318 laterally adjacent to both the base portion of the signal trace 310 but, more importantly, to the fork portion 310a.

FIG. 3B illustrates, in perspective form, a second exemplary embodiment of my invention. In this single-layer embodiment 300b, I have illustrated additional possible layouts of signal traces with respective reference traces. In addition, in this embodiment, I have illustrated one possible configuration for a terminating via 320.

FIG. 3C illustrates, in perspective form, a third exemplary embodiment of my invention. In this multi-layer embodiment 300c, I have illustrated more than one vertically-adjacent layer of signal/reference traces may be stacked one above another, each layer separated from a vertically-adjacent layer by an intervening layer of dielectric material. (Note 3: by “vertically adjacent” I mean that each co-planar layer of signal/reference traces is disposed vertically above/below the immediately-adjacent layer of signal/reference traces.) (Note 4: I have not expressly depicted this intervening insulating layer in order more clearly to depict the respective trace layers.)

FIG. 3D illustrates, as noted above, the relative dimensions that are pertinent to implementing my invention within a single electrically-conductive layer of signal/reference traces.

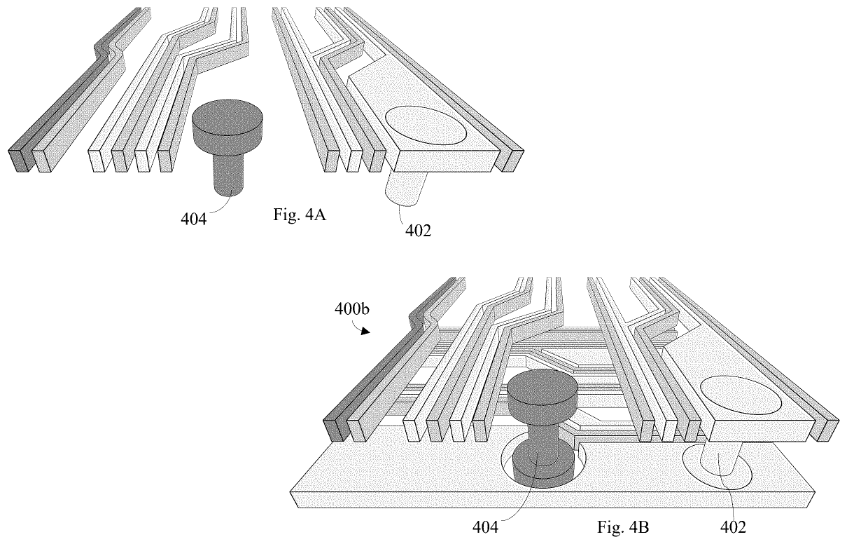

FIG. 4A illustrates, in perspective form, a fourth exemplary embodiment of my invention. In this single-layer embodiment 400a, I have illustrated more possible layouts of signal traces with respective reference traces. In addition, in this embodiment, I have illustrated both one possible configuration for another terminating via 402, and a through via 404.

FIG. 4B illustrates, in perspective form, a fifth exemplary embodiment of my invention. In this multi-layer embodiment 400b, I have illustrated another example of how more than one vertically-adjacent layer of signal/reference traces may be stacked one above another, each layer separated from a vertically-adjacent layer by an intervening layer of dielectric material. In particular, in this embodiment, I have illustrated how the via 402 may be used to connect signal traces between vertically-adjacent layers. In addition, in this embodiment, I have further illustrated how the via 404 may be routed through the lower layer for termination in the upper layer.

Let me now describe how I propose to implement my invention using presently-available manufacturing equipment: first, I will form an electrically-conductive signal trace having a first width W1 and a height T; then, I will form an electrically-conductive reference trace laterally adjacent to the signal trace, the reference trace having a second width W2, a height substantially equal to T, and spaced from the signal trace by a third width S1, wherein S1 is less than T; and finally, I will form a substantially planar layer by embedding the signal trace and the reference trace in a dielectric medium.

As will be clear to those familiar with the field of advanced packaging, the conductive material comprising the signal and reference traces will be sequentially: deposited using conventional equipment onto a suitable substrate; patterned using suitable equipment to form the desired configuration of signal and reference traces; and embedded into a substantially planar layer of dielectric medium. Typically, this layer is then processed to final dimensions. In a typical application, the electrically-conductive layers as disclosed herein comprise one or more layers of an advanced package.

The foregoing explanation described features of several embodiments so that those skilled in the art may better understand the scope of the invention. Those skilled in the art will appreciate that they may readily use the present disclosure as a basis for designing or modifying other processes and structures for carrying out the same purposes and/or achieving the same advantages of the embodiments herein. Such equivalent constructions do not depart from the spirit and scope of the present disclosure. Numerous changes, substitutions and alterations may be made without departing from the spirit and scope of the present invention.

Although illustrative embodiments of the invention have been described in detail with reference to the accompanying drawings, it is to be understood that the invention is not limited to those precise embodiments, and that various changes and modifications can be affected therein by one skilled in the art without departing from the scope of the invention as defined by the appended claims. Thus, it will be apparent to one of ordinary skill that this disclosure provides for improved method and apparatus for use in semiconductor packaging.

Apparatus, methods and systems according to embodiments of the disclosure are described. Although specific embodiments are illustrated and described herein, it will be appreciated by those of ordinary skill in the art that any arrangement which is calculated to achieve the same purposes can be substituted for the specific embodiments shown. This application is intended to cover any adaptations or variations of the embodiments and disclosure. For example, although described in terminology and terms common to the field of art, exemplary embodiments, systems, methods and apparatus described herein, one of ordinary skill in the art will appreciate that implementations can be made for other fields of art, systems, apparatus or methods that provide the required functions. The invention should therefore not be limited by the above-described embodiments, methods, and examples, but by all embodiments and methods within the scope and spirit of the invention.

In particular, one of ordinary skill in the art will readily appreciate that the names of the methods and apparatus are not intended to limit embodiments or the disclosure. Furthermore, additional methods, steps, and apparatus can be added to the components, functions can be rearranged among the components, and new components to correspond to future enhancements and physical devices used in embodiments can be introduced without departing from the scope of embodiments and the disclosure. One of skill in the art will readily recognize that embodiments are applicable to future systems, future apparatus, future methods, and different materials.

All methods described herein can be performed in a suitable order unless otherwise indicated herein or otherwise clearly contradicted by context. The use of any and all examples, or exemplary language (e.g., “such as”), is intended merely to better illustrate the disclosure and does not pose a limitation on the scope of the disclosure unless otherwise claimed. No language in the specification should be construed as indicating any non-claimed element as essential to the practice of the disclosure as used herein.

Terminology used in the present disclosure is intended to include all environments and alternate technologies that provide the same functionality described herein.

1. A method for forming a substantially planar electrically-conductive layer adapted to be fabricated into a package comprising a substrate having a substantially planar surface comprising a first plane, the method comprising the steps of:
forming an electrically-conductive signal trace oriented substantially in said first plane, the signal trace having a first width W1 and a height T, and extending within said first plane between a selected first point in said layer and a selected second point in said layer;
forming an electrically-conductive reference trace oriented substantially in said first plane laterally adjacent to the signal trace and extending within said first plane substantially from said first point to said second point, the reference trace having a second width W2, a height substantially equal to T, and spaced laterally from the signal trace by a third width S1, wherein S1 is less than T; and
forming said layer by embedding the signal trace and the reference trace in a dielectric medium.

2. The method of claim 1 wherein S1 is further characterized as being substantially less than T.

3. An electrically-conductive layer manufactured using the method of claim 1.

4. An advanced package comprising the electrically-conductive layer of claim 3.

5. The advanced package of claim 4 wherein the electrically-conductive layer is adapted to be connected to a selected one of a reference voltage or a ground voltage.

6. The advanced package of claim 4 further comprising a second electrically-conductive layer of claim 3.

7. An advanced package comprising an electrically-conductive layer manufactured using the method of claim 1.

8. A method for forming a substantially planar electrically-conductive layer adapted to be fabricated into a package comprising a substrate having a substantially planar surface comprising a first plane, the comprising the steps of:
forming an electrically-conductive signal trace oriented substantially in said first plane, said signal trace extending within said first plane between a selected first point in said layer and a selected second point in said layer, and having:
a first side;
a second side opposite said first side;
a top side;
a bottom side opposite said first top side;
a first width, W1, between said first side and said second side; and
a height, T, between said top side and said bottom side;
forming a first electrically-conductive reference trace oriented substantially in said first plane laterally adjacent to a selected first side of the signal trace and extending within said layer substantially from said first point to said second point, the first reference trace having a second width W2, a height substantially equal to T, and spaced from the first side of the signal trace by a third width S1, wherein S1 is less than T;
forming a second electrically-conductive reference trace laterally adjacent to a selected second side of the signal trace, the second reference trace having said second width W2, a height substantially equal to T, and spaced from the second side of the signal trace by said third width S1; and
forming said layer by embedding the signal trace and the reference traces in a dielectric medium.

9. The method of claim 8 wherein S1 is further characterized as being substantially less than T.

10. An electrically-conductive layer manufactured using the method of claim 8.

11. An advanced package comprising the electrically-conductive layer of claim 10.

12. The advanced package of claim 11 wherein the electrically-conductive layer is adapted to be connected to a selected one of a reference voltage or a ground voltage.

13. The advanced package of claim 11 further comprising a second electrically-conductive layer of claim 10.

14. An advanced package comprising an electrically-conductive layer manufactured using the method of claim 8.

15. A substantially planar electrically-conductive layer adapted to be fabricated into a package comprising a substrate having a substantially planar surface comprising a first plane, the layer comprising:
an electrically-conductive signal trace substantially oriented in said first plane, said signal trace extending within said first plane between a selected first point in said layer and a selected second point in said layer, and having:
a first side;
a second side opposite said first side;
a top side;
a bottom side opposite said first top side;
a first width, W1, between said first side and said second side; and
a height, T, between said top side and said bottom side;
a first electrically-conductive reference trace substantially oriented in said first plane laterally adjacent to a selected first side of the signal trace and extending within said layer substantially from said first point to said second point, the first reference trace having a second width W2, a height substantially equal to T, and spaced from the first side of the signal trace by a third width S1, wherein S1 is less than T;
a second electrically-conductive reference trace laterally adjacent to a selected second side of the signal trace, the second reference trace having said second width W2, a height substantially equal to T, and spaced from the second side of the signal trace by said third width S1; and
said layer embedding the signal trace and the reference traces.

16. The method of claim 15 wherein S1 is further characterized as being substantially less than T.

17. An advanced package comprising the electrically-conductive layer of claim 15.

18. The advanced package of claim 17 wherein the electrically-conductive layer is adapted to be connected to a selected one of a reference voltage or a ground voltage.

19. The advanced package of claim 18 further comprising a second, electrically-conductive layer of claim 15.
